(19) United States
(12) Patent Application Publication
(10) Pub. No.: US 2010/0327434 A1
(43) Pub. Date: Dec. 30, 2010

(54) SEMICONDUCTOR DEVICE AND METHOD OF MANUFACTURING THE SAME

(75) Inventor: Masaru YAJIMA, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/792,035

(22) Filed: Jun. 2, 2010

(30) Foreign Application Priority Data
Jun. 29, 2009 (JP) 2009-154095

(51) Int. Cl. H01L 23/48; H01L 21/50

(52) U.S. Cl. 257/737; 438/107; 257/777; 257/E23.01; 257/E21.499

(57) ABSTRACT

A semiconductor device includes: a first semiconductor chip having a first active surface and a bonding surface forming an opposite side of the first active surface, the bonding surface being bonded to a mounting surface of a substrate; a second semiconductor chip having a second active surface facing the first active surface, and stacked on the first semiconductor chip; a slope section having a sloping surface with a shape of smoothing a step between the first active surface and the mounting surface, and adapted to bury the step in at least a part of a periphery of the first semiconductor chip; and a first wiring wire laid down between the mounting surface and the first active surface via the sloping surface of the slope section, and connected to a first bump provided to the second active surface on the first active surface.

### BACKGROUND

1. Technical Field

The present invention relates to a semiconductor device and a manufacturing method thereof, and in particular to a semiconductor device having a multilayer structure with a plurality of semiconductor chips stacked on a substrate, and a method of manufacturing such a semiconductor device.

2. Related Art

In the past, as described in, for example, JP-A-2004-281539, in particular in FIG. 4 thereof, there has been known a semiconductor device having a multilayer structure with a plurality of semiconductor chips stacked on, for example, a printed-wiring board as a substrate provided with wiring. According to such a configuration, while keeping the mounting area of the semiconductor device substantially the same as the area of the board, the area where elements can be formed can be increased by stacking a plurality of semiconductor chips. In other words, it becomes possible to achieve both of downsizing and high-density integration of semiconductor devices.

Incidentally, in the semiconductor device described in the document cited above, a first semiconductor chip (a lower layer chip) is stacked on the substrate so that the active surface forms the upper surface. Further, the lower layer chip is entirely covered by an insulating layer having a thickness larger than the thickness of the lower layer chip including elements and wiring provided thereto, and a second semiconductor chip (an upper layer chip) is stacked on the upper surface of the insulating layer similarly so that the active layer forms the upper layer. Therefore, when electrically connecting the substrate and the upper layer chip to each other, or electrically connecting the lower layer chip and the upper layer chip to each other, wiring formed by providing a through hole to the insulating layer disposed between the lower layer chip and the upper layer chip and filling the through hole with a electrically conductive material becomes an essential constituent.

In other words, since in such related art there is adopted such a laminated structure as described above, namely the structure in which the active surface of the lower layer chip and the active surface of the upper layer chip are separated with a distance larger than the thickness of the semiconductor chip in the stacking direction of the semiconductor chip, the length of the wiring for connecting the substrate and the upper layer chip inevitably becomes longer in the stacking direction described above compared to the length of the wiring for connecting the substrate and the lower layer chip. If it is the configuration in which the wiring length becomes larger simply in a surface direction of the active surface, it is the configuration substantially the same as the configuration obtained by changing the planar arrangement of the wiring materials, and therefore, the mechanical and electrical characteristics of such wiring can easily be assured. However, if it is the configuration in which the wiring length is increased in the stacking direction, namely the normal direction of the active surface, it leads that the wiring material to be originally disposed in a planar direction is also stacked in the normal direction of the active surface. Generally, in such a structure, the density of the wiring material inevitably becomes spatially uneven compared to a simple planar wiring, and the mechanical and electrical characteristics of the wiring might be damaged, after all.

### SUMMARY

An advantage of some aspects of the invention is to provide a semiconductor device capable of reducing the size of the wiring connecting the substrate and the semiconductor chip to each other in the stacking direction of the semiconductor chip in the semiconductor device having the multilayer structure with a plurality of semiconductor chips stacked on the substrate, and a manufacturing method thereof.

According to an aspect of the invention, there is provided a semiconductor device including a first semiconductor chip having a first active surface and a bonding surface forming an opposite side of the first active surface, the bonding surface being bonded to a mounting surface of a substrate, a second semiconductor chip having a second active surface facing the first active surface, and stacked on the first semiconductor chip, a slope section having a sloping surface with a shape of smoothing a step between the first active surface and the mounting surface, and adapted to bury the step in at least a part of a periphery of the first semiconductor chip, and a first wiring wire laid down between the mounting surface and the first active surface via the sloping surface of the slope section, and connected to a first bump provided to the second active surface on the first active surface.

According to the configuration described above, the second semiconductor chip is stacked on the first semiconductor chip in a so-called face-down state in which the active surface of the second semiconductor chip faces the first semiconductor chip. Therefore, the first wiring wires for connecting the substrate and the second semiconductor chip can be formed on the upper surface of the first semiconductor chip via the upper surface of the slope section. Therefore, compared to the configuration of the related art of stacking the second semiconductor chip in a so-called face-up state in which the surface on the opposite side of the active surface of the second semiconductor chip faces the first semiconductor chip, the length of the first wiring wire can be reduced in the stacking direction of the semiconductor chips.

According to another aspect of the invention, in the semiconductor device described above, there is further provided a second wiring wire adapted to connect an electrode provided to the first active surface and a second bump provided to the second active surface.

According to the configuration described above, since the second semiconductor chip is stacked in the so-called face-down state in which the active surface of the second semiconductor chip faces the first semiconductor chip, it becomes possible to connect the electrode provided to the first active surface and the second bump provided to the second active surface to each other. Therefore, compared to the configuration of the related art of stacking the second semiconductor chip in a so-called face-up state in which the surface on the opposite side of the active surface of the second semiconductor chip faces the first semiconductor chip, the length of the second wiring wire can be reduced in the stacking direction of the semiconductor chips.

According to still another aspect of the invention, in the semiconductor device described above, a gap between the second active surface and the first active surface is filled with an underfill material.

According to the configuration described above, since the connection section with the wiring connected to the second semiconductor chip is covered by the underfill material, infiltration of the moisture and so on to the gap of the connection section can be avoided, and it becomes possible to prevent corrosion of the connection section.

According to yet another aspect of the invention, in the semiconductor device described above, the first semiconductor chip and the second semiconductor chip stacked on the substrate are covered with resin.

According to the configuration described above, since the first semiconductor chip and the second semiconductor chip are covered with the resin, the whole of the electrical connection section in these first and second semiconductor chips can be protected by the resin from corrosive matters such as moisture. Further, the elements provided to the first and second semiconductor chips can also be protected by the resin from the corrosive materials similarly to the connection section described above, the corrosion resistance property as the semiconductor device is improved.

According to still yet another aspect of the invention, there is provided a method of manufacturing a semiconductor device including bonding a first semiconductor chip and a substrate to each other with a bonding surface of the first semiconductor chip, forming an opposite side of an active surface of the first semiconductor chip, being bonded to the mounting surface of the substrate, forming a slope section having a sloping surface with a shape of smoothing a step between the first active surface and the mounting surface, to thereby bury the step in at least a part of a periphery of the first semiconductor chip, laying down a first wiring wire between the mounting surface and the first active surface so as to connect the mounting surface and the first active surface to each other by ejecting a plurality of droplets including a wiring material so that the mounting surface and the first active surface are connected by the droplets via a sloping surface of the slope section, and then curing the droplets, and stacking a second semiconductor chip on the first semiconductor chip while keeping a second active surface of the second semiconductor chip facing the first active surface so that a first bump provided to the second active surface is connected to the first wiring wire on the first active surface.

According to the manufacturing method described above, it is arranged that the second semiconductor chip is stacked in the so-called face-down state in which the active surface of the second semiconductor chip faces the first semiconductor chip. Therefore, it becomes possible to form the first wiring wire for connecting the substrate and the second semiconductor chip after forming the slope section described above only in the periphery of the first semiconductor chip. Therefore, compared to the configuration of the related art of stacking the second semiconductor chip in a so-called face-up state in which the surface on the opposite side of the active surface of the second semiconductor chip faces the first semiconductor chip, the length of the first wiring wire can be reduced in the stacking direction of the semiconductor chips. Moreover, compared to the manufacturing method of the related art in which the second semiconductor chip is stacked in the so-called face-up state in which the surface on the opposite side of the active surface of the second semiconductor chip faces the first semiconductor chip, it becomes possible to eliminate the process related to formation of the slope section and formation of the first wiring wire, it becomes possible to manufacture the semiconductor device as described above with a simpler and easier manufacturing method.

### BRIEF DESCRIPTION OF THE DRAWINGS

The invention will be described with reference to the accompanying drawings, wherein like numbers reference like elements.

FIG. 1 is a plan view showing a planar structure of a semiconductor device as an embodiment of the invention.

FIG. 2 is a cross-sectional view showing a cross-sectional structure of the semiconductor device along the line A-A shown in FIG. 1.

FIGS. 3A, 3B, and 3C are manufacturing process charts showing a manufacturing process of the semiconductor device.

FIGS. 4A and 4B are cross-sectional views showing a cross-sectional structure of a modified example.

### DESCRIPTION OF AN EXEMPLARY EMBODIMENT

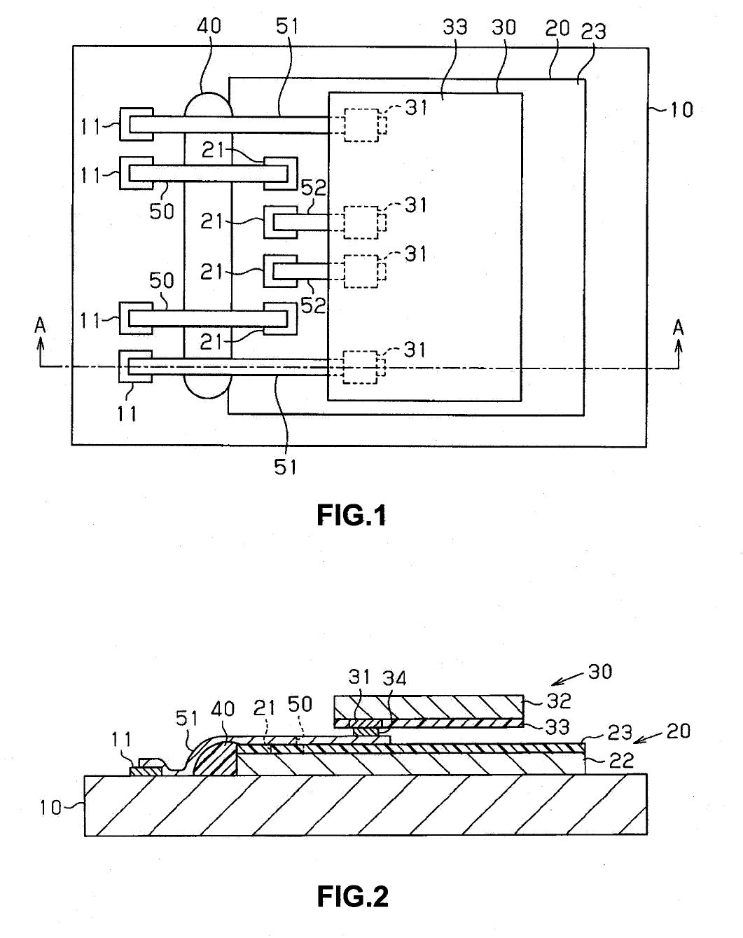

Hereinafter, a semiconductor device as an embodiment of the invention will be explained with reference to FIGS. 1, 2, and 3A through 3C.

FIG. 1 shows a planar structure of the semiconductor device, and FIG. 2 shows a cross-sectional structure of the semiconductor device along the line A-A shown in FIG. 1. As shown in FIGS. 1 and 2, on a principal surface (the upper surface in FIG. 2) of a mounting substrate 10 provided to the semiconductor device, there are laid down four substrate electrode pads 11 so as to be arranged in a line along one side of the principal surface. Hereinafter, the direction along which these substrate electrode pads 11 are arranged is defined as a column direction, further the direction perpendicular to the column direction on the mounting surface is defined as a row direction.

On the principal surface of the mounting substrate 10 described above, namely the mounting surface, there is mounted a lower layer chip 20 as a first semiconductor chip, which has a semiconductor substrate 22 and an insulating layer 23 stacked on the principal surface (the upper surface in FIG. 2) of the semiconductor substrate 22, so as to expose the four substrate electrode pads 11 provided to the mounting substrate 10 on the mounting surface. In the principal surface of the lower layer chip 20, there are buried four lower layer electrode pads 21, the surfaces of which are thus exposed, in a line along the column direction. The lower layer chip 20 having such a configuration is mounted in a so-called face-up state in which a surface on the opposite side of the active surface (a first active surface), the surface provided with the lower layer electrode pads 21, faces the mounting surface described above.

On the active surface of the lower layer chip 20 described above, there is mounted an upper layer chip 30 as a second semiconductor chip, which has a semiconductor substrate 32 and an insulating layer 33 stacked on the principal surface (the lower surface in FIG. 2) of the semiconductor substrate 32, so as to expose the four lower layer electrode pads 21 provided to the lower layer chip 20 on the active surface of the lower layer chip 20. In the principal surface of the upper layer chip 30, there are buried four upper layer electrode pads 31, the surfaces of which are thus exposed, similarly in a line along the column direction. The upper layer chip 30 having such a configuration is mounted in a so-called face-down state in which the active surface (a second active surface), the surface provided with the upper layer electrode pads 31, faces the active surface of the lower layer chip 20.

In the mounting structure described above, there is caused a step as a difference in level between the mounting surface of the mounting substrate 10 and the active surface of the lower layer chip 20. In the area where the step is caused, and in particular between the substrate electrode pads 11 provided to the mounting substrate 10 and the lower layer electrode pads 21 provided to the lower layer chip 20, there is buried a slope section 40 for smoothing the step described above. In other words, between the substrate electrode pads 11 and the lower layer electrode pads 21, there is buried the slope section 40 having a continuous slope from the active surface of the lower layer chip 20 to the mounting surface so as to have the largest thickness on the side of the lower layer chip 20 and to have the smallest thickness on the side of the substrate electrode pads 11.

Two lower layer wiring wires 50 are laid down along the row direction so as to extend from the respective two substrate electrode pads 11 laid down in a center area in the column direction among the four substrate electrode pads 11 provided to the mounting substrate 10 to the active surface of the lower layer chip 20 via the mounting surface and a sloping surface of the slope section 40 described above. These two lower layer wiring wires 50 are connected to the respective two lower layer electrode pads 21 laid down at the both ends in the column direction among the four lower layer electrode pads 21 laid down on the active surface of the lower layer chip 20. Further, the substrate electrode pads 11 provided to the mounting substrate 10 and the lower layer electrode pads 21 corresponding thereto are connected to each other by the two lower layer wiring wires 50, thus the mounting substrate 10 and the lower layer chip 20 are connected electrically to each other.

In addition, two upper layer wiring wires 51 are also laid down along the row direction so as to extend from the respective two substrate electrode pads 11 laid down at both ends in the column direction among the four substrate electrode pads 11 provided to the mounting substrate 10 described above to a gap between the active surface of the lower layer chip 20 and the active surface of the upper layer chip 30 via the mounting surface and the sloping surface of the slope section 40 described above similarly to the lower layer wiring wires 50. These two upper layer wiring wires 51 are connected to the respective two upper layer electrode pads 31 laid down at the both ends in the column direction among the four upper layer electrode pads 31 laid down on the active surface of the upper layer chip 30 via bump electrodes 34 provided respectively to the upper layer electrode pads 31. Further, the two substrate electrode pads 11 provided to the mounting substrate 10 and the upper layer electrode pads 31 corresponding thereto are connected to each other by the two upper layer wiring wires 51, thus the mounting substrate 10 and the upper layer chip 30 are connected electrically to each other.

Further, two inter-chip wiring wires 52 extending from the respective two lower layer electrode pads 21 laid down in a center area in the arranging direction among the four lower layer electrode pads 21 provided to the upper layer chip 20 to a gap between the lower layer chip 20 and the upper layer chip 30 along the active surface of the lower layer chip 20 are also laid down along the row direction. These two inter-chip wiring wires 52 are connected to the respective two upper layer electrode pads 31 laid down in a center portion in the column direction among the four upper layer electrode pads 31 laid down on the active surface of the upper layer chip 30 via the bump electrodes 34 provided respectively to the upper layer electrode pads 31. Further, the lower layer electrode pads 21 and the upper layer electrode pads 31 corresponding thereto are connected to each other by these two inter-chip wiring wires 52, thus the lower layer chip 20 and the upper layer chip 30 are connected electrically to each other.

According to such a mounting structure as described above, the upper layer chip 30 is stacked on the lower layer chip 20 in the so-called face-down state in which the active layer of the upper layer chip 30 faces the lower layer chip 20. Therefore, in the stacking direction of the semiconductor chip, the distance between the active surface of the lower layer chip 20 and the active surface of the upper layer chip 30 directly corresponds to the thickness of the bump electrode 34. In other words, it results that the distance between the active surface of the lower layer chip 20 and the active surface of the upper layer chip 30 are sufficiently reduced compared to the related art configuration in which the upper layer chip 30 is stacked in the so-called face-up state with the surface opposite to the active surface of the upper layer chip 30 facing the lower layer chip 20. Therefore, it results that in the wiring wires 51 connecting the mounting substrate 10 and the upper layer chip 30, the length of the semiconductor chip in the stacking direction thereof is reduced.

Moreover, according to the mounting structure described above, the upper layer wiring wires 51 extending from the mounting substrate 10 are connected to the upper layer chip 30 via such bump electrodes 34. Therefore, similarly to the lower layer wiring wires 50, it becomes possible for the upper layer wiring wires 51 connected to the mounting substrate 10 to be connected to the upper layer chip 30 providing the upper layer wiring wires 51 are stacked on the active surface of the lower layer chip 20. Therefore, it is not required to take a risk of increasing the wiring length of the upper layer wiring wires 51 or the inter-chip wiring wires 52 from the active surface of the lower layer chip 20 in the stacking direction of the semiconductor chip, and as a result, the length thereof in the stacking direction of the semiconductor chip can further be reduced.

Further, as the configuration of stacking the upper layer chip 30 in the face-up state described above, it is possible to adopt the configuration of, for example, laying down a slope section for smoothing the step as a difference in level between the active surface of the lower layer chip 20 and the active surface of the upper layer chip 30 besides the slope section 40 described above. In such a configuration, it results that the wiring wires 51 for connecting the mounting substrate 10 and the upper layer chip 30, namely the upper layer wiring wires 51 are also laid down on the sloping surface of the slope section provided to the step of the active surfaces of the lower layer chip 20 and the upper layer chip 30 in addition to the mounting surface of the mounting substrate 10, the sloping surface of the slope section 40, the active surface of the lower layer chip 20, and the active surface of the upper layer chip 30. Further, regarding the wiring wires 52 connecting the lower layer chip 20 and the upper layer chip 30, namely the inter-chip wiring wires 52, they are also laid down on the sloping surface of the sloping section provided to the step of the active surfaces of the lower layer chip 20 and the upper layer chip 30 in addition to the active surface of the lower layer chip 20 and the active surface of the upper layer chip 30, as a result.

In contrast thereto, according to the mounting structure described above, since it becomes needless to provide the slope section to the step between the active surface of the lower layer chip 20 and the active surface of the upper layer chip 30, in either of the cases of the upper layer wiring wires 51 and inter-chip wiring wires 52 described above, it becomes also needless to lay down the wires corresponding to the sloping surface of the slope section, in other words, the wires corresponding to the width of the slope section in the planar direction. Therefore, it becomes possible to reduce the length of the upper layer wiring wires 51 and the inter-chip wiring wires 52 in the planar direction compared to the configuration described above as an example.

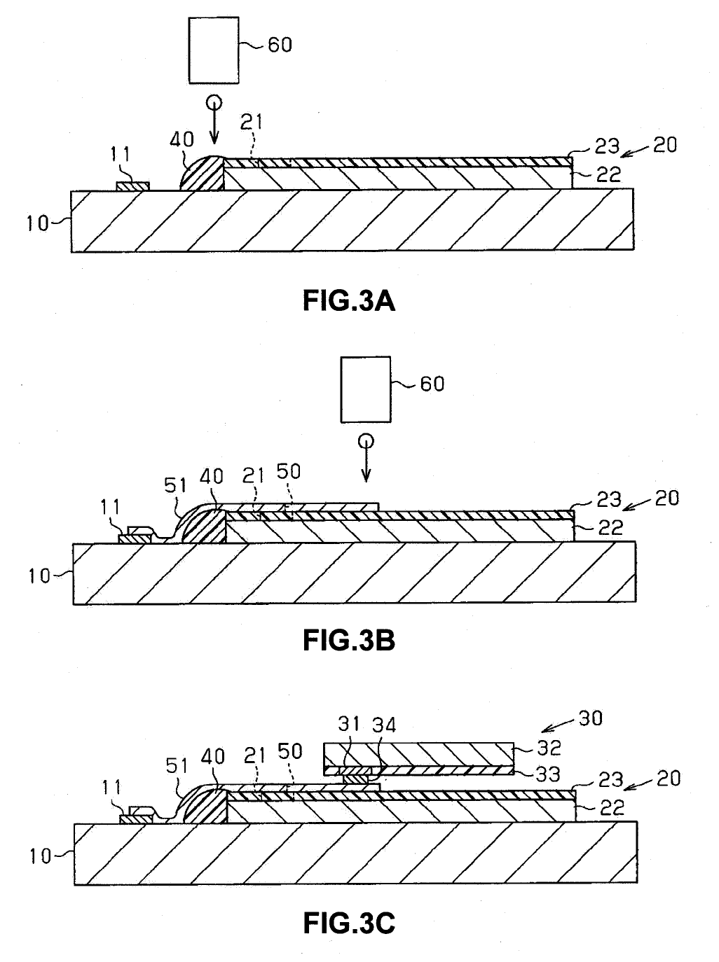

Then, a process of manufacturing such a semiconductor device will be explained with reference to FIGS. 3A through 3C. It should be noted that FIGS. 3A through 3C show a cross-sectional structure in the respective manufacturing processes corresponding to the cross-sectional structure of the semiconductor device, which is shown in FIG. 1 described above and manufactured through the manufacturing process, along the line A-A shown in FIG. 1.

FIGS. 3A through 3C show the process of manufacturing the semiconductor device described above using a manufacturing method of the semiconductor device according to the present embodiment. As shown in FIG. 3A, in the manufacturing method, firstly, a substrate having the substrate electrode pads 11 made of metal such as gold or aluminum, namely for example, a so-called rigid substrate such as a glass substrate, or a so-called flexible substrate such as a polyimide film or a polyester film, is formed as the mounting substrate 10. Then, the lower layer chip 20 having the lower layer electrode pads 21 and the insulating layer 23 surrounding the lower layer electrode pads 21 formed on the principal surface of the semiconductor substrate 22 made of a semiconductor material is mounted by a so-called face-up method, the method of making the bonding surface opposite to the surface provided with the lower layer electrode pads 21, namely the active surface, face the mounting substrate 10 described above. It should be noted that as the forming material of the insulating layer 23 provided to the lower layer chip 20, any resin materials having insulating property such as polyamide resin, epoxy resin, or fluorinated resin can arbitrarily be adopted.

When the lower layer chip 20 is mounted on the mounting substrate 10 as described above, a step is caused between the mounting surface of the mounting substrate 10 and the active surface of the lower layer chip 20. Therefore, in particular, in order for smoothing the step located on the side where the lower layer wiring wires 50 for connecting the substrate electrode pads 11 and the lower layer electrode pads 21 to each other or the upper layer wiring wires 51 for connecting the substrate electrode pads 11 and the upper layer electrode pads 31 to each other are laid down, there is formed the slope section 40 having a continuous slope from the mounting surface to the active layer of the lower layer chip 20 so as to have the largest thickness on the side of the lower layer chip 20. In more detailed description, a droplet including the forming material of the slope section 40, for example, resin ink including a resin material such as polyamide resin, is ejected to a forming area of the slope section 40 from a droplet ejection device 60 well known to the public. In this occasion, the slope section 40 described above is formed by continuously changing an amount of the forming material described above ejected from the droplet ejection device 60 so that the ejection amount becomes the maximum on the side of the lower layer chip 20 in the forming area of the slope section 40 and the minimum on the side of the substrate electrode pads 11. It should be noted that it is also possible to form the lower layer electrode pads 21 and the insulating layer 23 of the lower layer chip 20 by ejecting the material for forming them from the droplet ejection device 60.

Subsequently, as shown in FIG. 3B, the droplet including the forming material of the lower layer wiring wires 50, for example, silver ink including silver fine particles, is ejected by the droplet ejection device 60 on the laying areas of the lower layer wiring wires 50 for connecting the substrate electrode pads 11 of the mounting substrate 10 and the lower layer electrode pads 21 of the lower layer chip 20 to each other, namely the mounting surface and the active surface of the lower layer chip 20 via the sloping surface of the slope section 40 described above. On this occasion, on the mounting surface and the active surface of the lower layer chip 20, there are virtually partitioned not only the laying areas of the lower layer wiring wires 50 for connecting the substrate electrode pads 11 and the lower layer electrode pads 21 to each other, but also the laying areas of the upper layer wiring wires 51 for connecting the substrate electrode pads 11 and the upper layer electrode pads 31 to each other, and further the laying areas of the inter-chip wiring wires 52 for connecting the lower layer electrode pads 21 and the upper layer electrode pads 31 to each other. Therefore, it becomes possible to eject the material for forming the wiring wires 50, 51, 52 in a single ejection process to the laying areas of the lower layer wiring wires 50, the laying areas of the upper layer wiring wires 51, and the laying areas of the inter-chip wiring wires 52. In other words, in such a manufacturing method as described above, it becomes possible to eject the material for forming all of the lower layer wiring wires 50 for connecting the mounting substrate 10 and the lower layer chip 20 to each other, the upper layer wiring wires 51 for connecting the mounting substrate 10 and the upper layer chip 30 to each other, and the inter-chip wiring wires 52 for connecting the lower layer chip 20 and the upper layer chip 30 to each other in a single process.

In contrast, in the semiconductor device on which the upper layer chip 30 is mounted using the face-up method in which the surface opposite to the active surface of the upper layer chip 30 faces the active surface of the lower layer chip 20, namely the semiconductor device having the configuration of the related art, since it results that the wiring wires described above are to be formed on surfaces different from each other, and consequently, the material forming the wiring wires 50, 51, 52 is required to be ejected in the respective processes. Therefore, it is not avoidable that the number of processes of the manufacture becomes large compared to the method of manufacturing the semiconductor device according to the present embodiment. Therefore, according to the manufacturing method described above, it becomes possible to achieve reduction of the number of processes and simplification of the process content in the manufacturing process of the semiconductor device.

Further, it is true that the wiring wires 50, 51, 52 described above can also be formed by the ejection in a single process even in, for example, the configuration in which the upper layer chip 30 is mounted in the face-up state but is different from that of the semiconductor device of the related art, namely in the configuration in which as described above the slope section is laid down in the step between the active surface of the lower layer chip 20 and the upper layer chip 30 in addition to the slope section 40 laid down in the step between the mounting surface of the mounting substrate 10 and the active surface of the lower layer chip 20. However, in this case, restrictions on designing the semiconductor device such that it is not allowed to dispose the electrode pads 21 of the lower layer chip at the forming position of the slope section laid down in the step between the active surface of the lower layer chip 20 and the active surface of the upper layer chip 30, or that it is required to provide the laying area for the slope section on the active surface of the lower layer chip 20 are not avoidable.

In this respect, according to the semiconductor device related to the present embodiment, it is possible to form the wiring wires 50, 51, 52 described above by the ejection in a single process without such restrictions on the design, in other words, in the condition in which freedom of design is assured at a high level.

The droplet ejected to the laying areas of the respective wiring wires in the ejection process described above are dried while a part of the liquid component included therein is evaporated by heating. Subsequently, the semiconductor chip having the upper layer electrode pads 31 made of metal such as gold or aluminum, and the insulating layer 33 formed using a resin material so as to bury the upper layer electrode pads 31 and expose the surfaces thereof disposed on the upper surface of the semiconductor substrate 32 is formed as the upper layer chip 30. Subsequently, the bump electrodes 34 also made of metal such as gold or aluminum are formed on the upper layer electrode pads 31. Incidentally, it is also possible to form the upper electrode pads 31 and the insulating layer 33 provided to the upper layer chip 30 by ejecting the forming material thereof from the droplet ejection device 60 similarly to the substrate electrode pads 11 and the insulating layer 33 of the lower layer chip 20.

Then, as shown in FIG. 3C, the forming material of the wiring wires thus dried and the bump electrodes 34 are pressure-welded with each other in the laying areas of the upper layer wiring wires 51 and the laying areas of the inter-chip wiring wires 52 using the method of making the active surface of the upper layer chip 30 face the active surface of the lower layer chip 20, namely the face-down method. It should be noted that the bump electrode 34 for connecting the upper layer electrode pads 31 disposed on the active surface of the upper layer chip 30 and the upper layer wiring wires 51 or the inter-chip wiring wires 52, respectively, are arranged to be disposed previously on the upper layer electrode pads 31. Besides the above, it is also possible for the bump electrodes 34 to be disposed at the locations corresponding to the upper layer electrode pads 31 on the wiring material ejected on the active surface of the lower layer chip 20.

As described above, after mounting the upper layer chip 30 on the lower layer chip 20 using the face-down method, a heating process is executed on the mounting substrate 10 on which the upper layer chip 30 is mounted, and thus, the forming material of the wiring wires is burnt to form the wiring wires 50, 51, 52, and at the same time the bump electrodes 34 and the wiring wires 51, 52 are bonded to each other. On this occasion, it becomes possible to realize the burning process of the wiring wires 50, 51, 52 and the bonding process of the wiring wires 51, 52 to the bump electrodes 34 by a single process. Therefore, according to the manufacturing method described above, although the bonding process of the bump electrodes 34 and the wiring wires 51, 52 using the face-down method becomes necessary, such a bonding process can be realized in the burning process of the wiring wires, and therefore, it becomes possible to suppress increase in the number of processes and complication of the process content caused by the bonding process.

As explained hereinabove, according to the semiconductor device and the manufacturing method related to the present embodiment, it becomes possible to obtain the advantages recited as follows.

1. The upper layer chip 30 is mounted on the lower layer chip 20 in the so-called face-down state in which the active surface of the upper layer chip 30 faces the lower layer chip 20. Thus, it becomes possible to lay down the upper layer wiring wires 51 for connecting the mounting substrate 10 and the upper layer chip 30 from the mounting surface of the mounting substrate 10 to the active surface of the lower layer chip 20 via the sloping surface of the slope section 40. Therefore, compared to the configuration in which the upper layer chip 30 is stacked in the so-called face-up state in which the surface opposite to the active surface of the upper layer chip 30 faces the lower layer chip 20, it becomes possible to reduce the length of the upper layer wiring wires 51 in the stacking direction of the semiconductor chip, and at the same time, to reduce the space for disposing the upper layer wiring wires 51, and further, to achieve low-profiling as the semiconductor device.

It should be noted that even in the case in which the upper layer chip is stacked in the face-up state, it is also conceivable that the space for disposing the upper layer wiring wires 51 can be shrunk providing the configuration described below, for example, is adopted. Specifically, if the lower layer chip and the upper layer chip are each provided with a through hole penetrating it in the thickness direction, and the upper layer wiring wires are formed of the wiring wires via the through holes, it becomes possible to reduce the space for disposing the upper layer wiring wires.

However, in such a configuration, firstly, it is required to bore the through hole of the lower layer chip and the through hole of the upper layer chip on substantially the same axis. Here, if the semiconductor chip itself is thin, such a configuration as described above is also possible. However, if the semiconductor chip is thick, such through holes themselves are difficult to form. Moreover, the wiring wires formed inside the through holes need to be electrically isolated from the lower layer chip inside the through holes of the lower layer chip, and consequently, the structure of the lower layer chip itself becomes extremely complicated. In contrast thereto, according to the configuration described above, working on each of the semiconductor chips in the thickness direction thereof is completely eliminated, and it is not necessary to significantly change the structure of the semiconductor chip itself.

Moreover, since the upper layer chip 30 is stacked on the lower layer chip 20 after the upper layer wiring wires for connecting the mounting surface of the mounting substrate 10 and the active surface of the lower layer chip 20 between the mounting surface of the mounting substrate 10 and the active surface of the lower layer chip 20, when forming the upper layer wiring wires 51, obstacles thereto are reduced. Therefore, compared to the case of forming the upper layer wiring wires inside the through holes, working for forming the upper layer wiring wires 51 becomes easier. Further, even in the case of laying down the slope section 40 in the periphery of the lower layer chip 20, the configuration can be realized by simpler and easier working compared to the case of providing the through holes.

2. Further, according to the mounting structure using the face-down method described above, it becomes possible to connect the lower layer electrode pads 21 provided to the active surface of the lower layer chip 20 and the bump electrodes 34 disposed on the upper layer electrode pads 31 provided to the active surface of the upper layer chip 30 to each other. In other words, compared to the mounting structure using the face-up method described above, it becomes possible to reduce the length of the inter-chip wiring wires 52 in the stacking direction of the semiconductor chip, and at the same time, to shrink the space for disposing the inter-chip wiring wires 52.

3. In addition, as the configuration of stacking the upper layer chip 30 in the face-up state, the configuration of laying down the slope section also to the step between the active surface of the lower layer chip 20 and the active surface of the upper layer chip 30 is also possible. In such a configuration, it results that the upper layer wiring wires 51 is laid down also on the sloping surface of the slope section provided to the step of the respective active surfaces of the lower layer chip 20 and the upper layer chip 30 in addition to the mounting surface of the mounting substrate 10, the sloping surface of the slope section 40, the active surface of the lower layer chip 20, and the active surface of the upper layer chip 30. Further, it results that the inter-chip wiring wires 52 are also laid down on the sloping surface of the slope section provided to the step of the respective active surfaces of the lower layer chip 20 and the upper layer chip 30 in addition to the active surface of the lower layer chip 20 and the active surface of the upper layer chip 30.

In contrast thereto, according to the mounting structure of the semiconductor device related to the present embodiment, since it becomes needless to provide the slope section to the step between the active surface of the lower layer chip 20 and the active surface of the upper layer chip 30, in either of the cases of the upper layer wiring wires 51 and the inter-chip wiring wires 52 described above, it becomes also needless to lay down the wires corresponding to the sloping surface of the slope section, in other words, the wires corresponding to the width of the slope section in the planar direction. Therefore, it becomes possible to reduce the length of the upper layer wiring wires 51 and the inter-chip wiring wires 52 in the planar direction compared to the configuration described above as an example.

4. Further, according to the mounting structure using the face-down method described above, it is possible to form all of the lower layer wiring wires 50 for connecting the mounting substrate 10 and the lower layer chip 20 to each other, the upper layer wiring wires 51 for connecting the mounting substrate 10 and the upper layer chip 30 to each other, and the inter-chip wiring wires 52 for connecting the lower layer chip 20 and the upper layer chip 30 to each other in the same ejection process. In other words, compared to the manufacturing method of the semiconductor device using the face-up method of the related art, in other words, the manufacturing method in which the wiring wires 50, 51, 52 must be formed in the respective processes different from each other, it becomes possible to realize reduction of the number of processes and simplification of the process content thereof regarding the manufacturing process of the semiconductor device.

5. Further, it is true that the wiring wires 50, 51, 52 described above can also be formed by the ejection in a single process even in the configuration in which the upper layer chip 30 is mounted in the face-up state, and the slope section is laid down in the step between the active surface of the lower layer chip 20 and the upper layer chip 30 in addition to the slope section 40 laid down in the step between the mounting surface of the mounting substrate 10 and the active surface of the lower layer chip 20. However, in this case, restrictions on designing the semiconductor device such that it is not allowed to dispose the electrode pads 21 of the lower layer chip at the forming position of the slope section laid down in the step between the active surface of the lower layer chip 20 and the active surface of the upper layer chip 30, or that it is required to provide the laying area for the slope section on the active surface of the lower layer chip 20 are not avoidable.

In this respect, according to the semiconductor device related to the present embodiment, it is possible to form the wiring wires 50, 51, 52 described above by the ejection in a single process without such restrictions on the design, in other words, in the condition in which freedom of design is assured at a high level.

6. Moreover, since the structure in which the upper layer wiring wires 51 and the inter-chip wiring wires 52 are erected along the stacking direction of the semiconductor chip is not required, it becomes possible to apply a technology of executing the wiring work on a plane such as the mounting surface of the mounting substrate and the active surface of the lower layer chip, namely the inkjet method as the forming method of the wiring wires. Therefore, since it becomes possible to control the shape and the size of the upper layer wiring wires 51 and the inter-chip wiring wires 52 in units of droplet, it is obvious that miniaturization of the wires 51, 52 becomes possible, it becomes also possible to easily form the wires with complicated shapes, and the restriction on the layout of the electrode pads and the semiconductor chip can also be relaxed.

It should be noted that the embodiment described above can also be executed as the following aspects obtained by appropriately modifying the embodiment described above.

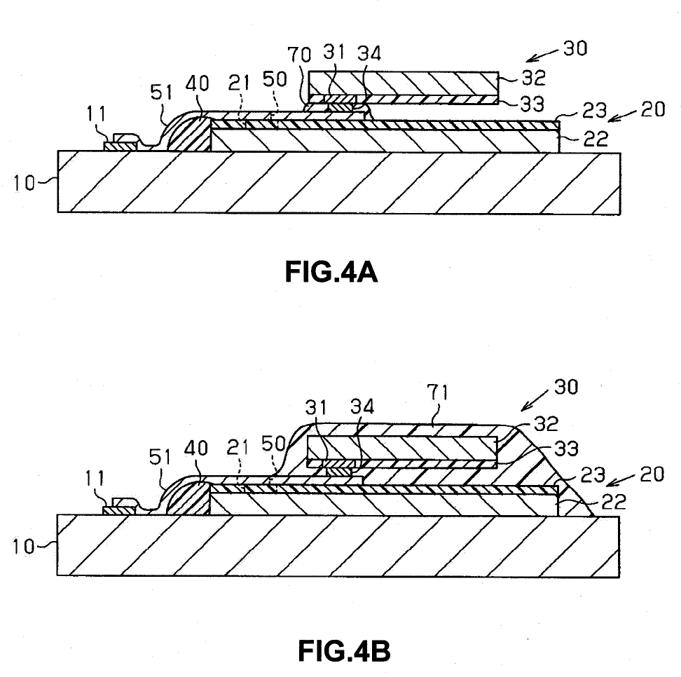

In the semiconductor device described above, as shown in FIG. 4A, it is also possible to fill the connection region between each of the wiring wires 51, 52 formed on the upper surface of the lower layer chip 20 and the bump electrodes 34 with an underfill material 70 made of a resin material such as epoxy resin. Thus, it becomes possible to obtain the following advantage in addition to the advantages 1 through 6 described above.

7. It become possible to avoid infiltration of moisture and so on to a gap in the connection section between the wiring wires 51, 52 disposed on the active surface of the lower layer chip 20 and the bump electrodes 34, namely the gap between the lower layer chip 20 and the upper layer chip 30, and thus, it becomes possible to prevent corrosion of the connection section.

Further, in the semiconductor device, as shown in FIG. 4B, it is also possible to cover the whole of the lower layer chip 20 and the upper layer chip 30 mounted on the mounting substrate 10 with molding resin 71 made of epoxy resin or silicone resin. Thus, it becomes possible to obtain the following advantage in addition to the advantages 1 through 6 described above.

8. It results that the whole of the electrical connection section in the lower layer chip 20 and the upper layer chip 30 is protected from corrosive matters such as moisture by the molding resin 71. Moreover, since it results that the inter-chip wiring wires 52 provided to the lower layer chip 20 and the upper layer chip 30 and the elements are also protected from the corrosive matters by the molding resin 71 similarly to the connection section described above, corrosion resistance property as the semiconductor device is improved.

Further, the configuration obtained by combining the configuration shown in FIG. 4A and the configuration shown in FIG. 4B, namely the configuration in which the connection section between the wires 51, 52 formed on the upper surface of the lower layer chip 20 and the bump electrodes 34 is filled with the underfill member 70, and at the same time, the whole of the lower layer chip 20 and the upper layer chip 30 is covered by the molding resin 71 described above is also possible.

It is arranged that the slope section 40 for burying the step as the difference in level between the mounting surface of the mounting substrate 10 and the active surface of the lower layer chip 20 is provided only to a part of the periphery of the lower layer chip 20, namely the side in the periphery on which the substrate electrode pads 11 of the mounting substrate 10 and the lower layer electrode pads 21 of the lower layer chip 20 are formed. It is also possible to provide the slope section 40 throughout the periphery of the lower layer chip 20 besides the configuration described above.

There is adopted the configuration of providing not only the upper layer wiring wires 51 for connecting the substrate electrode pads 11 of the mounting substrate 10 and the upper layer electrode pads 31 of the upper layer chip 30 to each other, but also the lower layer wiring wires 50 for electrically connecting the mounting substrate 10 and the lower layer chip 20 to each other, and further the inter-chip wiring wires 52 for electrically connecting the lower layer chip 20 and the upper layer chip 30 to each other. Besides the configuration described above, any semiconductor device provided with at least the upper layer wiring wires 51 can provide the advantage substantially identical to the advantage 1 described above.

The entire disclosure of Japanese Patent Application No. 2009-154095, filed Jun. 29, 2009 is expressly incorporated by reference herein.

What is claimed is:

1. A semiconductor device comprising:
a first semiconductor chip having a first active surface and a bonding surface forming an opposite side of the first active surface, the bonding surface being bonded to a mounting surface of a substrate;
a second semiconductor chip having a second active surface facing the first active surface, and stacked on the first semiconductor chip;
a slope section having a sloping surface with a shape of smoothing a step between the first active surface and the mounting surface, and adapted to bury the step in at least a part of a periphery of the first semiconductor chip; and
a first wiring wire laid down between the mounting surface and the first active surface via the sloping surface of the slope section, and connected to a first bump provided to the second active surface on the first active surface.

2. The semiconductor device according to claim 1, further comprising:
a second wiring wire adapted to connect an electrode provided to the first active surface and a second bump provided to the second active surface.

3. The semiconductor device according to claim 1, wherein
a gap between the second active surface and the first active surface is filled with an underfill material.

4. The semiconductor device according to claim 1, wherein
the first semiconductor chip and the second semiconductor chip stacked on the substrate are covered with resin.

5. A method of manufacturing a semiconductor device, comprising:
bonding a first semiconductor chip and a substrate to each other with a bonding surface of the first semiconductor chip, forming an opposite side of a first active surface of the first semiconductor chip, being bonded to the mounting surface of the substrate;
forming a slope section having a sloping surface with a shape of smoothing a step between the first active surface and the mounting surface, to thereby bury the step in at least a part of a periphery of the first semiconductor chip;
laying down a first wiring wire between the mounting surface and the first active surface so as to connect the mounting surface and the first active surface to each other by ejecting a plurality of droplets including a wiring material so that the mounting surface and the first active surface are connected by the droplets via a sloping surface of the slope section, and then curing the droplets; and
stacking a second semiconductor chip on the first semiconductor chip while keeping a second active surface of the second semiconductor chip facing the first active surface so that a first bump provided to the second active surface is connected to the first wiring wire on the first active surface.
